(19) United States
(12) Patent Application Publication
(10) Pub. No.: US 2013/0328209 A1
(43) Pub. Date: Dec. 12, 2013

(54) Stack Arrangement

(71) Applicants: Cheryl Sharmani Selvanayagam, Singapore (SG); Ranjan Rajoo, Singapore (SG); Xiaowu Zhang, Singapore (SG)

(72) Inventors: Cheryl Sharmani Selvanayagam, Singapore (SG); Ranjan Rajoo, Singapore (SG); Xiaowu Zhang, Singapore (SG)

(73) Assignee: Agency for Science, Technology and Research, Singapore (SG)

(21) Appl. No.: 13/576,655

(22) PCT Filed: Feb. 12, 2010
(86) PCT No.: PCT/SG2010/000057

§ 371 Date: Nov. 20, 2012

(51) Int. Cl. H01L 23/48

(52) U.S. Cl. CPC H01L 23/481
USPC 257/774

(57) ABSTRACT

In an embodiment, a stack arrangement is provided. The stack arrangement may include a semiconductor arrangement, the semiconductor arrangement including a substrate; a via formed through the substrate; and a conductive portion arranged in the via. The stack arrangement may further include an interconnect portion arranged over the via; a bond pad portion arranged between the semiconductor arrangement and the interconnect portion, the bond pad portion may include a bond pad circumferential portion arranged at least partially circumferential with respect to the via and at a first distance away from the conductive portion; and at least one bond pad electrical connection extending from within the bond pad circumferential portion to the conductive portion; wherein the interconnect portion may be arranged away from the conductive portion via the bond pad portion.

### TECHNICAL FIELD

Embodiments relate to a stack arrangement.

### BACKGROUND

Low temperature bonds or joints are thin intermetallic bonds that are formed between two devices or components when plated layers of different metals on each side of the respective components come into contact under relatively low temperature and high pressure. These joints including mainly intermetallic compounds, may fail in a sudden unexpected manner, compared to normal solder joints which may fail in a ductile manner where cracks may grow more slowly. The problem of weak interconnects may be further exacerbated when these thin interconnections may be formed on pads located above a through-silicon via (TSV).

When a change in temperature occurs, a mismatch in coefficient of thermal expansion (CTE) may cause copper inside the TSV to expand or contract much more than the surrounding silicon. This may result in unexpectedly high tensile stresses in the joints. At bond formation temperature, the copper in the TSV may expand more than the silicon, initially compressing the joint. On cooling, the copper may contract to the original configuration, thereby resulting in a pre-stressed bond that may experience tensile forces at its center and compressive forces at its edges. This additional tensile stress on post-formation cooling to room temperature may increase a likelihood of joint failure. This phenomenon may be expected in thin interconnects and microbumps which are placed on TSVs.

Therefore, there is a need for an alternative stack arrangement for stacking devices or components which may decrease the tensile stress exerted on the joint and enhance the reliability of the joint to a large extent.

### SUMMARY

In various embodiments, a stack arrangement may be provided. The stack arrangement may include a semiconductor arrangement, the semiconductor arrangement including a substrate; a via formed through the substrate; and a conductive portion arranged in the via. The stack arrangement may further include an interconnect portion arranged over the via; a bond pad portion arranged between the semiconductor arrangement and the interconnect portion, the bond pad portion may include a bond pad circumferential portion arranged at least partially circumferential with respect to the via and at a first distance away from the conductive portion; and at least one bond pad electrical connection extending from within the bond pad circumferential portion to the conductive portion; wherein the interconnect portion may be arranged away from the conductive portion via the bond pad portion.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of various embodiments. In the following description, various embodiments of the invention are described with reference to the following drawings, in which:

FIG. 1A shows a cross-sectional view of a stack arrangement including a bond pad portion, the bond pad portion including a bond pad circumferential portion according to an embodiment; FIG. 1B shows a top view of the stack arrangement along A-A as shown in FIG. 1A according to an embodiment;

FIG. 2A shows a top view of a bond pad portion including a square-shape bond pad circumferential portion according to an embodiment; FIG. 2B shows a top view of a bond pad portion including an octagon-shape bond pad circumferential portion according to an embodiment; FIG. 2C shows a top view of a bond pad portion including a substantially circular-shape bond pad circumferential portion according to an embodiment;

FIG. 3A shows a top view of a bond pad portion including a circular-shape bond pad circumferential portion and bond pad electrical connections arranged in a first design according to an embodiment; FIG. 3B shows a top view of a bond pad portion including a circular-shape bond pad circumferential portion and bond pad electrical connections arranged in a second design according to an embodiment; FIG. 3C shows a top view of a bond pad portion including a circular-shape bond pad circumferential portion and a bond pad electrical connection with a third design according to an embodiment;

FIG. 4A shows a stack arrangement with a first configuration according to an embodiment; FIG. 4B shows a stack arrangement with a second configuration according to an embodiment; FIG. 4C shows a stack arrangement with a third configuration according to an embodiment; FIG. 4D shows a stack arrangement with a fourth configuration according to an embodiment;

FIG. 5A shows a global model of a stack arrangement including a bond pad portion, the bond pad portion including a bond pad circumferential portion according to an embodiment; FIG. 5B shows a sub-model model of a highlighted portion of the stack arrangement as shown in FIG. 5A according to an embodiment;

FIG. 6A shows a stress contour of a highlighted portion of the stack arrangement as shown in FIG. 5A based on a fully filled bond pad portion according to an embodiment; FIG. 6B shows a stress contour of a highlighted portion of the stack arrangement as shown in FIG. 5A based on a partially filled bond pad portion according to an embodiment;

FIG. 7A shows a stack arrangement including one fully filled bond pad portion positioned on one surface of an interconnect portion and another fully filled further bond pad portion positioned on an opposite surface of the interconnect portion, the stack arrangement used in a mechanical simulation modeling according to an embodiment; FIG. 7B shows a stack arrangement including one partially filled bond pad portion positioned on one surface of an interconnect portion and a fully filled bond pad portion positioned on an opposite surface of the interconnect portion, the stack arrangement used in a mechanical simulation modelling according to an embodiment;

FIG. 8A shows a stress contour, plot of stress contours in an axial direction of the simulation model of the stack arrangement as shown in FIG. 7A according to an embodiment; FIG. 8B shows a stress contour plot of stress contours in an axial direction of the simulation model of the stack arrangement as shown in FIG. 7B according to an embodiment;

FIG. 9A shows a plot of stress versus distance along a mid-plane of an interconnect portion for a respective fully filled bond pad portion and a partially filled bond pad portion according to an embodiment; FIG. 9B shows a stress contour plot of stress contours in an axial direction of a simulation model of a stack arrangement including a partially filled bond pad portion according to an embodiment;

FIG. 10A shows a plot of percentage decrease in stress versus bond pad circumferential portion width according to an embodiment; FIG. 10B shows a side view of a stack arrangement including a partially filled bond pad portion according to an embodiment; and

FIG. 11A shows a top view image of a bond pad portion according to an embodiment; FIG. 11B shows a corresponding schematic view of the bond pad portion of FIG. 11A according to an embodiment.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

The word “exemplary” is used herein to mean “serving as an example, instance, or illustration”. Any embodiment or design described herein as “exemplary” is not necessarily to be construed as preferred or advantageous over other embodiments or designs.

An embodiment may provide a stack arrangement. The stack arrangement may include a semiconductor arrangement, the semiconductor arrangement including a substrate; a via formed through the substrate; and a conductive portion arranged in the via. The stack arrangement may further include an interconnect portion arranged over the via; a bond pad portion arranged between the semiconductor arrangement and the interconnect portion, the bond pad portion may include a bond pad circumferential portion arranged at least partially circumferential with respect to the via and at a first distance away from the conductive portion; and at least one bond pad electrical connection extending from within the bond pad circumferential portion to the conductive portion; wherein the interconnect portion may be arranged away from the conductive portion via the bond pad portion.

In an embodiment, the first distance may vary according to via size and via pitch depending on design and user requirements. As an example, for a via diameter of about 50 μm, the first distance may be in a range of about 2 μm to about 5 μm

In an embodiment, the semiconductor arrangement may be termed as a chip.

In an embodiment, the substrate may include a top surface and a bottom surface. The top surface may be arranged substantially parallel to the bottom surface. The via may extend from the top surface through to the bottom surface of the substrate. Alternatively, the via may extend from the bottom surface up to the top surface of the substrate. The via may be of an uniform or changing cross-sectional dimension or diameter along the length of the via from the top surface through to the bottom surface of the substrate. For example, the via may be a cylindrical portion or a tapered portion.

In an embodiment, the conductive portion may fill the via. The conductive portion may partially or substantially fill the via depending on design and user requirements.

In an embodiment, the via may include at least one sidewall (i.e. the wall forming the respective side of the via). As an example, for a cylindrical via, there may be one sidewall as there may only be one cylindrical face (i.e outward facing portion). For vias of other shapes, for example a square via, there may be four sidewalls. Each of the at least one sidewall may extend in a direction substantially perpendicular to the respective top surface or bottom surface of the substrate.

In an embodiment, the conductive portion may be arranged along the at least one sidewall of the via. The conductive portion may partially or substantially line the respective sidewall of the via.

In an embodiment, the interconnect portion may include a filled portion or a partially filled portion. The partially filled portion may include an interconnect circumferential portion surrounding a hollow body. For example, the interconnect portion may be a filled ring or a partially filled ring depending on design and user requirements.

In an embodiment, the interconnect portion may include a cross-sectional shape selected from a group consisting of square, hexagon, circle, for example.

In an embodiment, the interconnect circumferential portion may include a single continuous portion or a plurality of discontinuous portions coupled in a predetermined arrangement or shape.

In an embodiment, the interconnect circumferential portion may vary depending on design and user requirements. For a via diameter of about 50 μm, the interconnect circumferential portion may include a cross-sectional dimension in the range of about 2 μm to about 5 μm.

In an embodiment, the bond pad circumferential portion may at least partially surround an opening of the via. The bond pad circumferential portion may be positioned on or above the substrate such that the bond pad circumferential portion may at least partially or substantially surround the opening of the via.

In an embodiment, the bond pad circumferential portion may include a thickness greater than a thickness of the at least one bond pad electrical connection. The difference in thickness between the bond pad circumferential portion and the at least one bond pad electrical connection may vary depending on user and design requirements. The ratio of the thickness between the bond pad circumferential portion and the at least one bond pad electrical connection may vary depending on design and user requirements and equipment capability.

In an embodiment, the bond pad circumferential portion may include a cross-sectional shape selected from a group consisting of square, hexagon, circle, for example.

In an embodiment, the bond pad circumferential portion may include a single continuous portion or a plurality of discontinuous portions coupled in a predetermined arrangement or shape.

In an embodiment, the bond pad circumferential portion may vary depending on design and user requirements. As an example, for a via diameter of about 50 μm, the bond pad circumferential portion may include a cross-sectional dimension in the range of about 2 μm to about 5 μm.

In an embodiment, the bond pad circumferential portion may be substantially aligned with the interconnect circumferential portion. As an example, the bond pad circumferential portion may be of a similar or different cross-sectional dimension from the interconnect circumferential portion. The respective bond pad circumferential portion and the interconnect circumferential portion may be sized accordingly so that there may be an overlap between the bond pad circumferential portion and the interconnect circumferential portion.

In an embodiment, the at least one bond pad electrical connection may extend from the bond pad circumferential portion along a surface of the substrate to the conductive portion. The at least one bond pad electrical connection may also be termed a trace or a redistribution layer. As an example, if the conductive portion may not substantially fill the via or the conductive portion may not fully line the respective sidewalls of the via, there may be a possibility for the at least one bond pad electrical connection to be extended along the respective one or more sidewalls of the via so as to be in contact with the conductive portion in the via.

In an embodiment, the at least one bond pad electrical connection may include a plurality of bond pad electrical connections. The number of at least one bond pad electrical connection may vary depending on design and user requirements.

In an embodiment, the plurality of bond pad electrical connections may be arranged within the bond pad circumferential portion such that the plurality of bond pad electrical connections may be linked at a common position. Each of the plurality of bond pad electrical connections may be spaced at a fixed distance or varying distance away from each other. The plurality of bond pad electrical connections may be arranged in an ordered or random arrangement depending on user and design requirements. The plurality of bond pad electrical connections may be arranged in any suitable arrangement or interconnected with each other as long as one of the bond pad electrical connection may connect the bond pad circumferential portion to the conductive portion arranged in the via.

In an embodiment, the plurality of bond pad electrical connections may also be arranged outside the bond pad circumferential portion such that the plurality of bond pad electrical connections may be configured for an external connection, i.e. as a redistribution layer (RDL).

In an embodiment, the stack arrangement may further include a further semiconductor arrangement arranged over the interconnect portion. The further semiconductor arrangement may be the same as the semiconductor arrangement. The further semiconductor arrangement may also be termed as a chip.

In an embodiment, the further semiconductor arrangement may further include a further substrate. Like the substrate, the further substrate may also include a top surface and a bottom surface. The top surface may be arranged substantially parallel to the bottom surface. The further via may extend from the top surface through to the bottom surface of the further substrate. The further via may be of an uniform or changing cross-sectional dimension along the length of the further via from the top surface through to the bottom surface of the further substrate, or vice versa. For example, the further via may be a cylindrical portion or a tapered portion.

In an embodiment, the further semiconductor arrangement may further include a further via formed in the further substrate; and a further conductive portion arranged in the further via. The position of the further via may or may not be aligned with the position of the via. The diameter of the further via may or may not be substantially the same as the diameter of the via. In order to save estate space on the stack arrangement, the further via may be aligned substantially along a same axis as the via and the interconnect portion or may overlap substantially with the via and the interconnect portion.

In an embodiment, the further conductive portion fills the further via. Like the conductive portion, the further conductive portion may partially or substantially fill the further via depending on design and user requirements.

In an embodiment, the further via may include at least one sidewall. Like the via, the at least one sidewall of the further via may extend in a direction substantially perpendicular to the respective top surface or bottom surface of the further substrate.

In an embodiment, the further conductive portion may be arranged along the at least one sidewall of the further via. The further conductive portion may partially or substantially line the respective sidewalls of the further via.

In an embodiment, the stack arrangement may further include a further bond pad portion arranged between the further semiconductor arrangement and the interconnect portion.

In an embodiment, the further bond pad portion may be same or different from the bond pad portion.

In an embodiment, the further bond pad portion may include a filled portion.

In an embodiment, the further bond pad portion may include a further bond pad circumferential portion arranged at least partially circumferential with respect to the further via and at a second distance away from the further conductive portion; and at least one further bond pad electrical connection extending from the further bond pad circumferential portion to the further conductive portion.

In an embodiment, the second distance may vary depending on design and user requirement. For a via diameter of about 50 μm, the second distance may be in a range of about 2 μm to about 5 μm.

In an embodiment, the further bond pad circumferential portion may at least partially surround a further opening of the further via. The further bond pad circumferential portion may be positioned on or above the further substrate such that the further bond pad circumferential portion may at least partially or substantially surround the further opening of the further via.

In an embodiment, the further bond pad circumferential portion may include a thickness greater than a thickness of the at least one further bond pad electrical connection. The difference in thickness between the further bond pad circumferential portion and the at least one bond pad electrical connection may vary depending on user and design requirements. The ratio of the thickness between the further bond pad circumferential portion and the at least one bond pad electrical connection may vary depending on design and user requirements and equipment capability.

In an embodiment, the further bond pad circumferential portion may include a cross-sectional shape selected from a group consisting of square, hexagon, circle, for example.

In an embodiment, the further bond pad circumferential portion may include a single continuous portion or a plurality of discontinuous portions coupled in a predetermined arrangement or shape.

In an embodiment, the further bond pad circumferential portion may vary depending on design and user requirement. For a via diameter of about 50 μm, the further bond pad circumferential portion may include a cross-sectional dimension in the range of about 2 μm to about 5 μm.

In an embodiment, the further bond pad circumferential portion may be substantially aligned with the interconnect circumferential portion and the bond pad circumferential portion. As an example, the bond pad circumferential portion, the further bond pad circumferential portion and the interconnect circumferential portion may be of similar or different cross-sectional dimension. The respective bond pad circumferential portion, the further bond pad circumferential portion and the interconnect circumferential portion may be sized so that there may be an overlap or connection between the respective bond pad circumferential portion, the further bond pad circumferential portion and the interconnect circumferential portion.

In an embodiment, the at least one further bond pad electrical connection may extend from within the further bond pad circumferential portion along a surface of the further substrate to the further conductive portion. The at least one further bond pad electrical connection may extend from within the further bond pad circumferential portion in any suitable manner to the further conductive portion. The at least one further electrical connection may be similar to the at least one electrical connection. The at least one further electrical connection may also be termed a trace. Like the at least one electrical connection as mentioned previously, if the further conductive portion may not substantially fill the further via or the further conductive portion may not fully line the respective sidewalls of the further via, there may be a possibility for the at least one further bond pad electrical connection to be extended along the respective one or more sidewalls of the further via so as to be in contact with the further conductive portion in the further via.

In an embodiment, the at least one further bond pad electrical connection may include a plurality of further bond pad electrical connections. Like the at least one bond pad electrical connection, the number of at least one further bond pad electrical connection may vary depending on design and user requirements.

In an embodiment, the plurality of further bond pad electrical connections may be arranged within the further bond pad circumferential portion such that the plurality of further bond pad electrical connections may be linked at a common position. The common position may be a position where some or all of the plurality of further bond pad electrical connections may intersect. Further, the common position may be a position which may overlap with the position of the further conductive portion in the further via.

In an embodiment, the plurality of further bond pad electrical connections may also be arranged outside of the further bond pad circumferential portion such that the plurality of further bond pad electrical connections may be connected to an external device.

In an embodiment, the substrate may include a material selected from a group consisting of silicon (Si), silicon-germanium (Si—Ge), gallium-arsenide (GaAs), for example. In an embodiment, the further substrate may include a material selected from a group consisting of silicon, silicon-germanium, gallium-arsenide (GaAs), for example.

In an embodiment, the substrate may be of a same or different material as the further substrate. The substrate may be of a same or different configuration as the further substrate.

In an embodiment, the conductive portion may include a material selected from a group consisting of copper, titanium, tungsten, chromium, tantalum, nickel, aluminium, for example.

In an embodiment, the further conductive portion may include a material selected from a group consisting of copper, titanium, tungsten, chromium, tantalum, nickel, aluminium, for example.

In an embodiment, the further conductive portion may be of a same or different material as the conductive portion. The further conductive portion may be of a same or different configuration as the conductive portion.

In an embodiment, the bond pad portion may include a material selected from a group consisting of copper, gold, titanium, chromium, tantalum, nickel, aluminium, for example.

In an embodiment, the further bond pad portion may include a material selected from a group consisting of copper, gold, titanium, chromium, tantalum, nickel, aluminium, for example.

In an embodiment, the bond pad portion may be of a same or different material as the further bond pad portion. The bond pad portion may be of a same or different configuration as the further bond pad portion.

In an embodiment, the at least one bond pad electrical connection may include a material selected from a group consisting of copper, gold, titanium, chromium, tantalum, nickel, aluminium, for example.

In an embodiment, the at least one further bond pad electrical connection may include a material selected from a group consisting of copper, gold, titanium, chromium, tantalum, nickel, aluminium, for example.

In an embodiment, the at least one bond pad electrical connection may be of a same or different material as the at least one further bond pad electrical connection. The at least one bond pad electrical connection may be of a same or different configuration as the at least one further bond pad electrical connection.

In an embodiment, the bond pad circumferential portion may be of a same or different material as the at least one bond pad electrical connection. The bond pad circumferential portion may be of a same or different configuration as the at least one bond pad electrical connection.

In an embodiment, the further bond pad circumferential portion may be of a same or different material as the at least one further bond pad electrical connection.

In an embodiment, the interconnect portion may include an intermetallic compound. For example, the intermetallic compound may include a Sn—In alloy with a melting point <156° C. Other intermetallic compounds may include gold-indium alloys, such as AuIn₂ (with a melting point of about 484° C.) and AuIn (with a melting point of about 484° C.), a gold-tin alloy AuSn (with a melting point of about 312° C.), and a gold-indium-tin alloy Au₄In₃Sn₃ (with a melting point of about 431° C.).

In an embodiment, the interconnect portion may include a material or a combination of materials selected from a group consisting of tin, indium, silver, gold, copper, for example.

In an embodiment, the interconnect portion, the bond pad circumferential portion, the further bond pad circumferential portion may be of a same shape or a different shape depending on user and design requirements.

In an embodiment, a bond pad design for low stress in microbumps on TSVs may be disclosed.

In an embodiment, thin interconnect portions and microbumps located above TSVs may be subjected to an additional tensile force on post-formation cooling to room temperature. The mismatch in CTE may cause the copper in the TSV to contract much more than the surrounding silicon, resulting in a localized vertical contraction of the copper in the TSV. The vertical contraction may exert a tensile stress in the interconnect portion or joint, increasing the likelihood of failure of the joint. This situation of high stress in the joint may be overcome by a bond pad design which may decouple the interconnect portion from the TSV such that contraction of the copper in the TSV may not transmitted to the joint. Simulation results show that with the proposed pad design, maximum tensile stress in the interconnect portion may decrease by about 50%.

In an embodiment, when a thin interconnect (i.e. interconnect portion) such as an intermetallic bond or a microbump may be placed on a TSV, the large contraction of the copper in the TSV may result in a tensile stress exerted in the interconnect portion during post-formation cooling to room temperature. Decoupling the contraction of the copper in the TSV from the intermetallic joint (i.e. interconnect portion) would decrease the tensile stress exerted on the intermetallic joint and enhance the reliability of the intermetallic joints to a large extent.

In an embodiment, the proposed design of the bond pad portion may include a bond pad circumferential portion and at least one bond pad electrical connection. The bond pad circumferential portion may be one in which there may not be a direct contact or connection between the bond pad circumferential portion and the copper-filled via. The bond pad circumferential portion may be shaped such that the bond pad circumferential portion may substantially surround the via, completely or otherwise, but may not be in contact with the via. The positioning of the bond pad circumferential portion with respect to the via may be such that the bond pad circumferential portion and the via may be coaxial. Electrical connectivity between the via and the bond pad circumferential portion may be provided through the presence of traces or bond pad electrical connections which may be thinner than the bond pad circumferential portion. One possible design may be a ring-shaped bond pad circumferential portion. With this design, the joint or the interconnect portion may wet (or stick) only to the bond pad circumferential portion and not the traces or the via positioned in between. Naturally, the decreased bonding area between the interconnect portion and the bond pad circumferential portion may affect bond strength. However, the width (w) of the ring-shaped bond pad circumferential portion as well as the distance (d) away from the via may be parameters that may be changed or tweaked during a design process for optimizing reliability and bonding quality. Such a design may effectively decouple the via from the interconnect portion, such that the interconnect portion may be unaffected by any contraction of the conductive portion in the TSV. This may result in significantly decreased tensile stress. This proposed design may not involve any additional fabrication or material cost. Fabrication of the bond pad portion may only involve a change in the mask design.

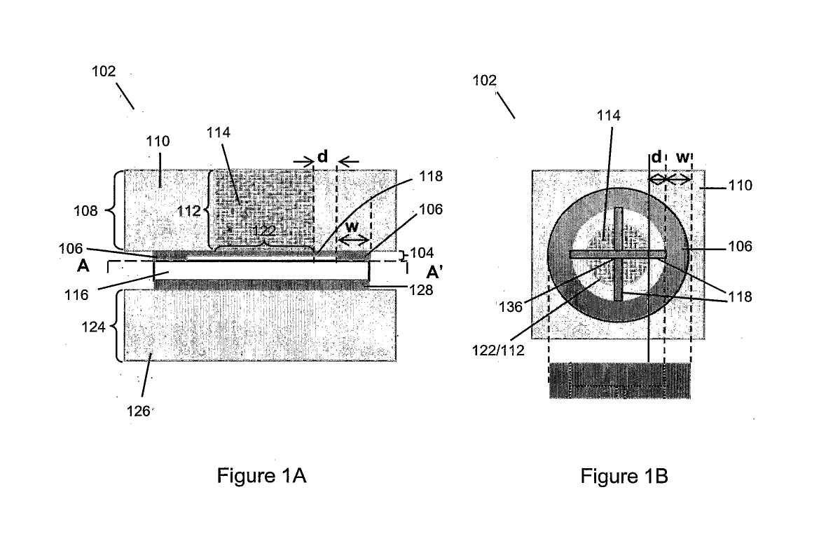

FIG. 1A shows a cross-sectional view of a stack arrangement 102 including a bond pad portion 104, the bond pad portion 104 including a bond pad circumferential portion 106 according to an embodiment.

The stack arrangement 102 may include a semiconductor arrangement 108, the semiconductor arrangement 108 including a substrate 110; a via 112 formed through the substrate 110; and a conductive portion 114 arranged in the via 112. The stack arrangement 102 may further include an interconnect portion 116 arranged below the via 112 and the bond pad portion 104 arranged between the semiconductor arrangement 108 and the interconnect portion 116. The bond pad portion 104 may include a bond pad circumferential portion 106 arranged at least partially circumferential with respect to the via 112 at a first distance (d) away from the conductive portion 114; and at least one bond pad electrical connection 118 extending from within the bond pad circumferential portion 106 to the conductive portion 114. The interconnect portion 116 may be arranged away from the conductive portion 114 via the bond pad portion 104.

In FIG. 1A, the conductive portion 114 may include a solid portion or a substantially filled portion which may substantially fill the via 112.

Further, the interconnect portion 116 may include a solid portion or a substantially filled portion. The interconnect portion 116 may include a cross-sectional shape selected from a group consisting of square, hexagon, circle, for example.

The bond pad circumferential portion 106 may include a thickness greater than a thickness of the at least one bond pad electrical connection 118.

The bond pad circumferential portion 106 may at least partially surround an opening 122 of the via 112. The bond pad circumferential portion 106 may include a circular shape and be of a single continuous portion. The bond pad circumferential portion 106 may vary depending on design and user requirements.

The at least one bond pad electrical connection 118 may extend from the bond pad circumferential portion 106 along a surface of the substrate 110 to the conductive portion 114. The at least one bond pad electrical connection 118 may include a plurality of bond pad electrical connections 118. The plurality of bond pad electrical connections 118 may be arranged within the bond pad circumferential portion 106 such that the plurality of bond pad electrical connections 118 may be linked at a common position (not shown).

The stack arrangement 102 may further include a further semiconductor arrangement 124 arranged below the interconnect portion 116. The further semiconductor arrangement 124 may further include a further substrate 126.

The stack arrangement 102 may further include a further bond pad portion 128 arranged between the further semiconductor arrangement 124 and the interconnect portion 116.

Unlike the bond pad portion 104 which may include a partially filled portion, the further bond pad portion 128 may include a substantially filled portion. However, the further bond pad portion 128 may also be of a similar or different configuration from the bond pad portion 104.

In an embodiment, the further bond pad portion 128 may include a thickness same or different from the thickness of the bond pad circumferential portion 106.

The further bond pad portion 128 may include any suitable cross-sectional shape selected from a group consisting of square, hexagon, circle, for example. The further bond pad portion 128 may include a cross-sectional shape same or different from the bond pad circumferential portion 106.

The further bond pad portion 128 may vary depending on design and user requirements.

In an embodiment, the substrate 110 may include a material selected from a group consisting of silicon, silicon-germanium, for example The further substrate 126 may include a material selected from a group consisting of silicon, silicon-germanium, gallium-arsenide (GaAs), for example. The substrate 110 may be of a same or different material as the further substrate 126.

In an embodiment, the conductive portion 114 may include a material selected from a group consisting of copper, titanium, tungsten, chromium, tantalum, nickel, aluminium, for example.

In an embodiment, the bond pad portion 104 may include a material selected from a group consisting of copper, gold, titanium, chromium, tantalum, nickel, aluminium, for example. The further bond pad portion 128 may include a material selected from a group consisting of copper, gold, titanium, chromium, tantalum, nickel, aluminium, for example.

The bond pad portion 104 may be of a same or different material as the further bond pad portion 128.

In an embodiment, the at least one bond pad electrical connection 118 may include a material selected from a group consisting of copper, gold, titanium, chromium, tantalum, nickel, aluminium, for example.

In an embodiment, the bond pad circumferential portion 106 may be of a same material as the at least one bond pad electrical connection 118.

In an embodiment, the interconnect portion 116 may include an intermetallic compound, for example Sn—In, AuIn₂, AuIn, AuSn, Au₄In₃Sn₃. The interconnect portion 116 may include a material or a combination of materials selected from a group consisting of gold, titanium, chromium, tantalum, nickel, aluminium, for example.

In an embodiment, the interconnect portion 116, the bond pad circumferential portion 106, the further bond pad portion 128 may be of a same shape or a different shape.

In an embodiment, the interconnect portion 116, the bond pad circumferential portion 106, the further bond pad portion 128 may be vertically aligned together or may be arranged such that there may be at least some overlap between the interconnect portion 116, the bond pad circumferential portion 106 and the further bond pad portion 128.

FIG. 1B shows a top view of the stack arrangement 102 along A-A′ as shown in FIG. 1A according to an embodiment.

The bond pad circumferential portion 106 may at least partially or substantially surround an opening 122 of the via 112. The bond pad circumferential portion 106 may include a circular shape and be of a single continuous portion. The bond pad circumferential portion 106 may include a cross-sectional dimension or width (w) which may vary depending on design and user requirements.

The at least one bond pad electrical connection 118 may extend from the bond pad circumferential portion 106 along a surface of the substrate 110 to the conductive portion 114. The at least one bond pad electrical connection 118 may include a plurality of bond pad electrical connections 118, for example two bond pad electrical connections 118 as shown in FIG. 1A. The two bond pad electrical connections 118 may be arranged within the bond pad circumferential portion 106 such that the two bond pad electrical connections 118 may be linked at a common position 136. For example, the two bond pad electrical connections 118 may be arranged such that the two bond pad electrical connections 118 may be arranged substantially perpendicular to each other. The two bond pad electrical connections 118 may be arranged such that the two bond pad electrical connections 118 may be linked at the centre of the bond pad circumferential portion 106. The centre of the bond pad circumferential portion 106 may correspond to the location of the conductive portion 114 in the via 112.

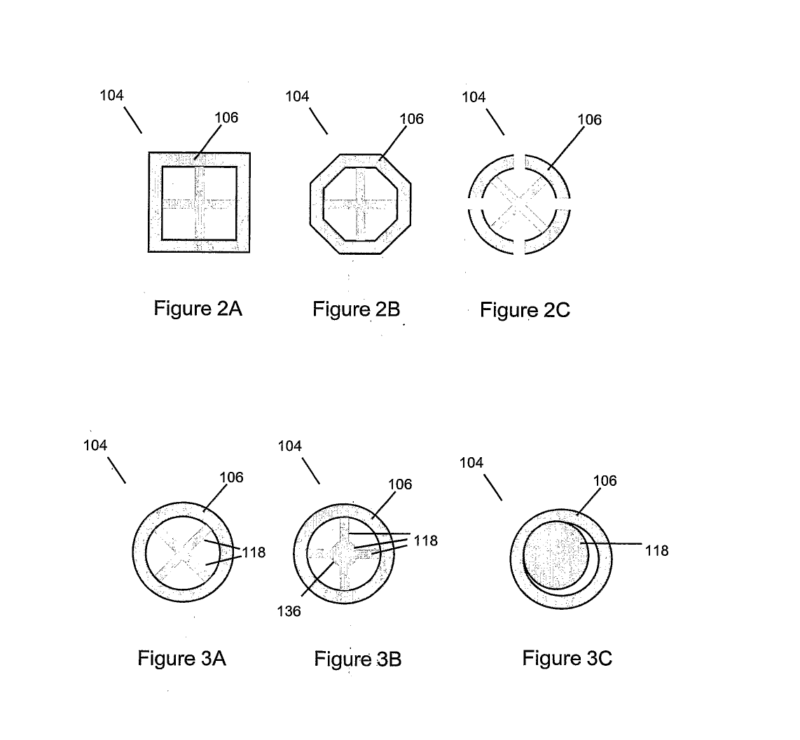

FIG. 2A shows a top view of a bond pad portion 104 including a square-shape bond pad circumferential portion 106 according to an embodiment; FIG. 2B shows a top view of a bond pad portion 104 including an octagon-shape bond pad circumferential portion 106 according to an embodiment; FIG. 2C shows a top view of a bond pad portion 104 including a substantially circular-shape bond pad circumferential portion 106 according to an embodiment.

The bond pad circumferential portion 106 may include any suitable shape depending on user and design requirements. For example, the bond pad circumferential portion 106 may include a single continuous portion like in FIG. 2A and FIG. 2B or a plurality of discontinuous portions like in FIG. 2C.

FIG. 3A shows a top view of a bond pad portion 104 including a circular-shape bond pad circumferential portion 106 and bond pad electrical connections 118 arranged in a first design according to an embodiment; FIG. 3B shows a top view of a bond pad portion 104 including a circular-shape bond pad circumferential portion 106 and bond pad electrical connections 118 arranged in a second design according to an embodiment; FIG. 3C shows a top view of a bond pad portion 104 including a circular-shape bond pad circumferential portion 106 and a bond pad electrical connection 118 with a third design according to an embodiment.

FIG. 3A shows a circular-shape bond pad circumferential portion 106 with two bond pad electrical connections 118 arranged within the bond pad circumferential portion 106 such that the two bond pad electrical connections 118 may be linked at a common position 136. The two bond pad electrical connections 118 may be arranged substantially perpendicular to each other within the bond pad circumferential portion 106.

FIG. 3B also shows a circular shape bond pad circumferential portion 106 with two bond pad electrical connections 118 arranged within the bond pad circumferential portion 106 such that the two bond pad electrical connections 118 may intersect or be linked at a common position 136. There may be an additional circular bond pad electrical connection 118 positioned at the intersection of the two bond pad electrical connections 118 or the common position 136. The additional bond pad electrical connection 118 may be aligned with the position of the conductive portion (not shown) in the via (not shown) so as to allow a bigger surface area for connection with conductive portion. The additional bond pad electrical connection 118 may be of any suitable shape or size depending on user and design requirements.

FIG. 3C shows a circular-shape bond pad circumferential portion 106 and a bond pad electrical connection 118 with a third design according to an embodiment. The bond pad electrical connection 118 may be of a circular shape as shown in FIG. 3C instead of an elongated shape as shown in FIGS. 3A and 3B. However, the bond pad electrical connection 118 may also include any other suitable shapes. The bond pad electrical connection 118 may be positioned or sized so as to be in contact with both the bond pad circumferential portion 106 and the conductive portion (not shown).

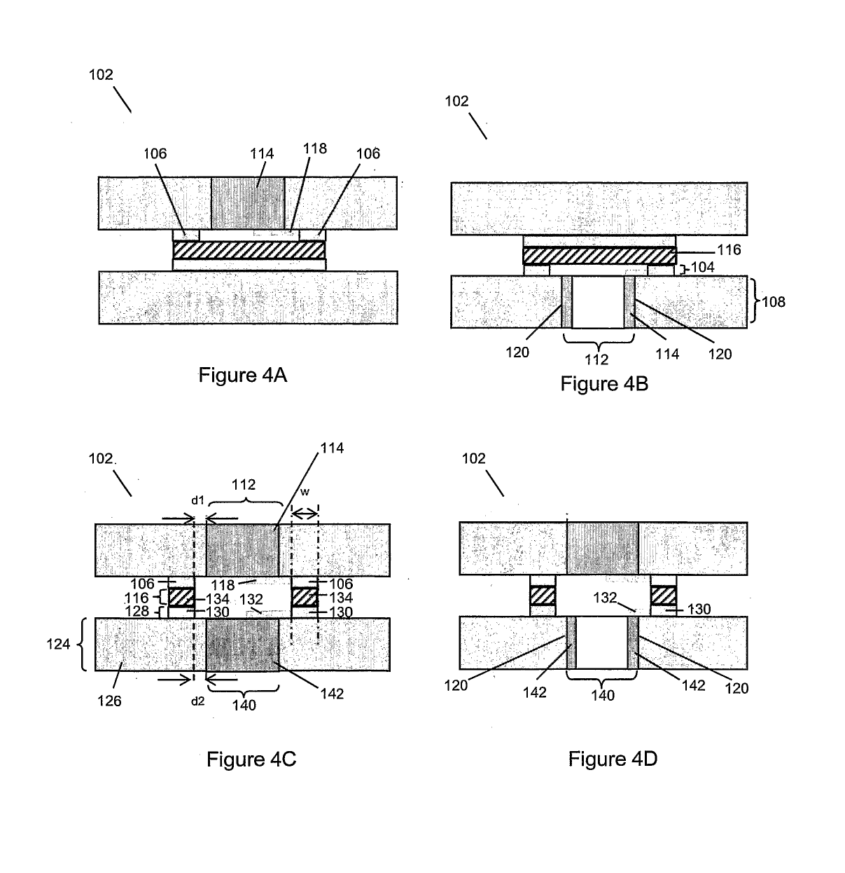

FIG. 4A shows a stack arrangement 102 with a first configuration according to an embodiment.

The stack arrangement 102 in FIG. 4A may be similar to the stack arrangement 102 in FIG. 1A with the difference such that in FIG. 4A, the bond pad electrical connection 118 may extend only from one end of the bond pad circumferential portion 106 to the conductive portion 114 while in FIG. 1A, the bond pad electrical connection 118 may extend from one end of the bond pad circumferential portion 106 across the conductive portion 114 to an opposite end of the bond pad circumferential portion 106. Any position, design or number of the bond pad electrical connection 118 may be possible as long as the bond pad circumferential portion 106 may be connected to the conductive portion 114.

FIG. 4B shows a stack arrangement 102 with a second configuration according to an embodiment.

The stack arrangement 102 in FIG. 4B may be similar to the stack arrangement 102 in FIG. 4A with the difference in the positioning of the semiconductor arrangement 108 and the bond pad portion 104 relative to the interconnect portion 116. There may be a further difference in the filling of the conductive portion 114 in the via 112.

In FIG. 4B, the semiconductor arrangement 108 and the bond pad portion 104 may be arranged below the interconnect portion 116 unlike in FIG. 4A, where the semiconductor arrangement 108 and the bond pad portion 104 may be arranged above the interconnect portion 116. The semiconductor arrangement 108 may be arranged at any suitable position relative to the interconnect portion 116 depending on user and design requirements.

Further, as shown in FIG. 4B, the via 112 may include at least one sidewall 120 (depending on the shape, there may be to be more than one sidewall 120) and the conductive portion 114 may be arranged along the at least one sidewall 120 of the via 112 such that the core of the via 112 may be substantially hollow. This may be different from the conductive portion 114 in FIG. 4A where the conductive portion 114 may substantially fill the via 112.

FIG. 4C shows a stack arrangement 102 with a third configuration according to an embodiment.

The stack arrangement 102 in FIG. 4C may be similar to the stack arrangement 102 in FIG. 4A with the difference in the design of the further semiconductor arrangement 124 and the corresponding further bond pad portion 128. Further, there may be a difference in the design of the interconnect portion 116.

In FIG. 4C, the further semiconductor arrangement 124 may include a further substrate 126. The further semiconductor arrangement 124 may include a further via 140 formed in the further substrate 126 and a further conductive portion 142 arranged in the further via 140. The further conductive portion 142 may substantially fill the further via 140. This may be unlike the stack arrangement 102 in FIG. 4A where the further semiconductor arrangement 124 may include a further substrate 126 with no further via 140 or even no further conductive portion 142 arranged in the further via 140.

In FIG. 4C, with the presence of the further conductive portion 142, the further bond pad portion 128 may include a further bond pad circumferential portion 130 arranged at least partially circumferential with respect to the further via 140 and at a second distance (d2) away from the further conductive portion 142. The further bond pad portion 128 may include at least one further bond pad electrical connection 132 extending from the further bond pad circumferential portion 130 to the further conductive portion 142.

In FIG. 4C, the bond pad circumferential portion 106 may also be arranged at least partially circumferential with respect to the via 112 and at a first distance (d1) away from the conductive portion 114. The first distance (d1) may be the same or different from the second distance (d2). Correspondingly, the bond pad electrical connection 118 may be similar or different in length from the further bond pad electrical connection 132 as long as the respective bond pad electrical connection 118 or further bond pad electrical connection 132 may be in contact with the respective conductive portion 114 or further conductive portion 142.

Further, the interconnect portion 116 as shown in FIG. 4C may include a partially filled portion unlike the interconnect portion 116 as shown in FIG. 4A which may include a substantially fully filled portion. The interconnect portion 116 as shown in FIG. 4C may include an interconnect circumferential portion 134 surrounding a hollow body. The cross-sectional dimension or width of the interconnect circumferential portion 134 may be comparable to that of the cross-sectional dimension or width (w) of the bond pad circumferential portion 106 or the further bond pad circumferential portion 130.

FIG. 4D shows a stack arrangement 102 with a fourth configuration according to an embodiment.

The stack arrangement 102 in FIG. 4D may be similar to the stack arrangement 102 in FIG. 4C, with the difference in the filling of the further conductive portion 142 in the further via 140 and the length of the further bond pad electrical connection 132 from the further bond pad circumferential portion 130 to the further conductive portion 142.

In FIG. 4D, the further via 140 may include at least one sidewall 120 and the further conductive portion 142 may be arranged along the at least one sidewall 120 of the further via 140 such that the core of the further via 140 may be hollow. In this regard, the further via 140 may be partially filled with the further conductive portion 142 and this may be different from that as shown in FIG. 4C where the further via 140 may be substantially filled with the further conductive portion 142.

Further, because of the partial filling of the further via 140, the length of the further bond pad electrical connection 132 may be shorter than that of the further bond Pad electrical connection 132 as shown in FIG. 4C. However, the further bond pad electrical connection 132 as shown in FIG. 4C may also be of the same shorter length as shown in FIG. 4D as long as the further bond pad circumferential portion 130 may be in contact with the further conductive portion 142.

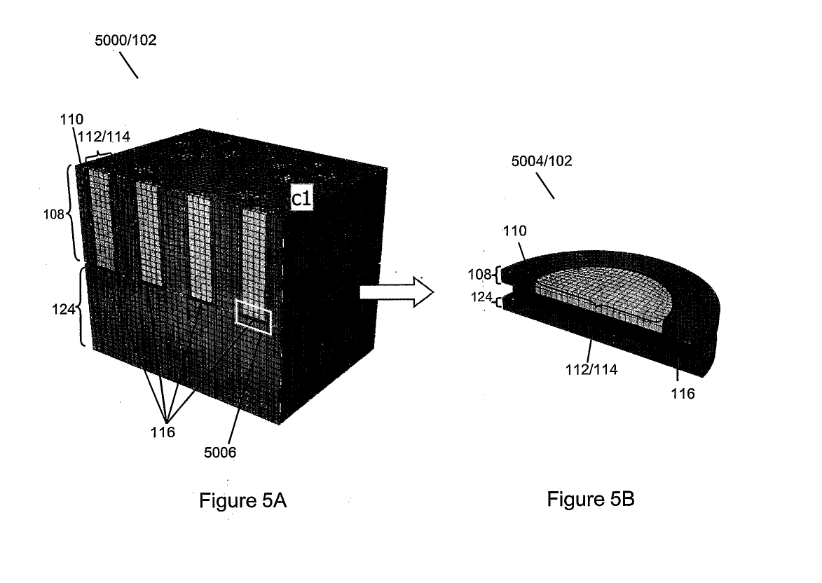

FIG. 5A shows a global model 5000 of a stack arrangement 102 including a bond pad portion (not shown), the bond pad portion including a bond pad circumferential portion according to an embodiment; FIG. 5B shows a sub-model model 5004 of a highlighted portion 5006 of the stack arrangement 102 as shown in FIG. 5A according to an embodiment.

Mechanical modeling simulations may be carried out to determine the effectiveness of the stack arrangement 102 including the proposed partial bond pad portion design. In particular, tensile stresses which tend to pry open the interconnect portion 116 or joint may be compared for two designs, namely the usual full bond pad portion and the proposed partial bond pad portion.

As the area of concern may be the relatively small bond in a large wafer-to-wafer bonded structure, and analysing such a detailed large model may use up a lot of computer time, a submodelling method may be used. With the submodelling method, a large model with a coarse mesh may first modeled as shown in FIG. 5A. The results from this large model as shown in FIG. 5A may then be applied as boundary conditions to a finely-mesh cut-out of the original model. These cut-out may be termed a submodel and one such submodel 5004 may be shown in FIG. 5B.

Each of the respective models 5000, 5004 in FIGS. 5A and 5B may show a stack arrangement 102. The stack arrangement 102 may include a semiconductor arrangement 108. The semiconductor arrangement 108 may include a substrate 110, a via 112 formed through the substrate 110, a conductive portion 114 arranged in the via 112. The stack arrangement 102 may further include an interconnect portion 116 arranged below the via 112. The stack arrangement 102 may also include a bond pad portion (not shown) arranged between the semiconductor arrangement 108 and the interconnect portion 116. The stack arrangement 102 may include a further semiconductor arrangement 124 arranged below the interconnect portion 116.

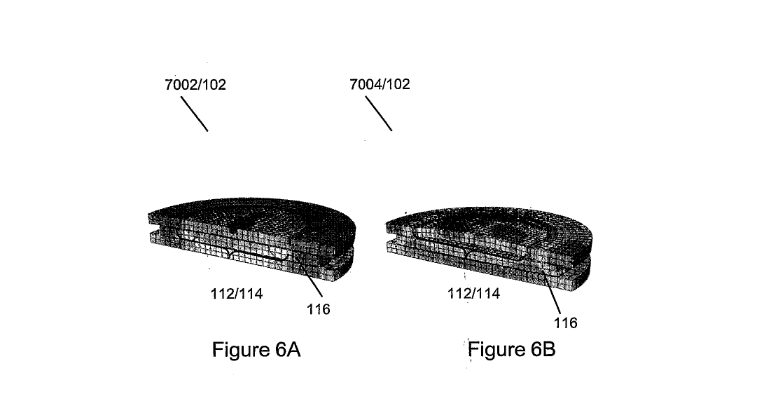

FIG. 6A shows a stress contour 7002 of a highlighted portion 7006 of the stack arrangement 102 as shown in FIG. 5A based on a fully filled bond pad portion (not shown) according to an embodiment. In FIG. 6A, the conductive portion 114 in the via 112 may be connected to the interconnect portion 116 via the fully filled bond pad portion. In this regard, with the fully filled bond pad portion, FIG. 6A shows that when the conductive portion 114 contracts, the conductive portion 114 may pull the interconnect portion 116 along with it. This may result in tensile stresses in the interconnect portion 116.

FIG. 6B shows a stress contour 7004 of the highlighted portion 7006 of the stack arrangement 102 as shown in FIG. 5A based on a partially filled bond pad portion (not shown) according to an embodiment.

In FIG. 6B, the conductive portion 114 in the via 112 may be connected to the interconnect portion 116 via the partially filled bond pad portion. The partially filled bond pad portion may include a bond pad circumferential portion arranged at least partially circumferential with respect to the via 112 and at a first distance away from the conductive portion 114. The bond pad portion may include at least one bond pad electrical connection extending from within the bond pad circumferential portion to the conductive portion 114. In this regard, the interconnect portion 116 may be arranged away from the conductive portion 114 via the partially filled bond pad portion.

As there may not be any direct bond formed between the conductive portion 114 and the interconnect portion 116, FIG. 6B shows that the conductive portion 114 contracts without pulling the interconnect portion 116 along with it.

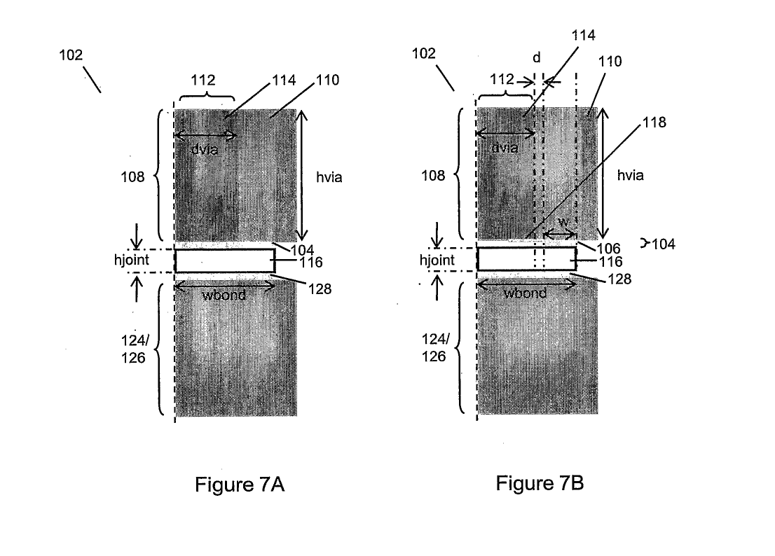

FIG. 7A shows a stack arrangement 102 including one fully filled bond pad portion 104 positioned on one surface of an interconnect portion 116 and another fully filled further bond pad portion 128 positioned on an opposite surface of the interconnect portion 116, the stack arrangement 102 used in a mechanical simulation modeling according to an embodiment; FIG. 7B shows a stack arrangement 102 including one partially filled bond pad portion 104 positioned on one surface of an interconnect portion 116 and a fully filled further bond pad portion 128 positioned on an opposite surface of the interconnect portion 116, the stack arrangement 102 used in a mechanical simulation modeling according to an embodiment.

Each of the respective stack arrangements 102 in FIG. 7A and FIG. 7B may include a semiconductor arrangement 108, the semiconductor arrangement 108 including a substrate 110; a via 112 formed through the substrate 110; and a conductive portion 114 arranged in the via 112. The stack arrangement 102 may further include an interconnect portion 116 arranged over the via 112; a bond pad portion 104 arranged between the semiconductor arrangement 108 and the interconnect portion 116.

The stack arrangement 102 may further include a further semiconductor arrangement 124 arranged below the interconnect portion 116. The further semiconductor arrangement 124 may further include a further substrate 126.

The stack arrangement 102 may further include a further bond pad portion 128 arranged between the further semiconductor arrangement 124 and the interconnect portion 116.

The via 112 in the substrate 110 may include a height (hvia) of about 200 μm for example. The via 112 may include a diameter (dvia) of about 25 μm for example. The conductive portion 114 may substantially fill the via 112.

Further, the interconnect portion 116 may include a filled portion. The interconnect portion 116 may include a height (hjoint) of about 5 μm for example.

The further bond pad portion 128 may include a diameter (wbond) for example, of about 35 μm.

The stack arrangement 102 in FIG. 7B may be similar to the stack arrangement 102 in FIG. 7A with the difference in the design of the bond pad portion 104.

FIG. 7A shows one fully filled bond pad portion 104 positioned on one surface of an interconnect portion 116 and another fully filled further bond pad portion 128 positioned on an opposite surface of the interconnect portion 116. In more details, FIG. 7A shows the fully filled bond pad portion 104 positioned between the interconnect portion 116 and the conductive portion 114 and the fully filled further bond pad portion 128 positioned between the interconnect portion 116 and the further semiconductor arrangement 124.

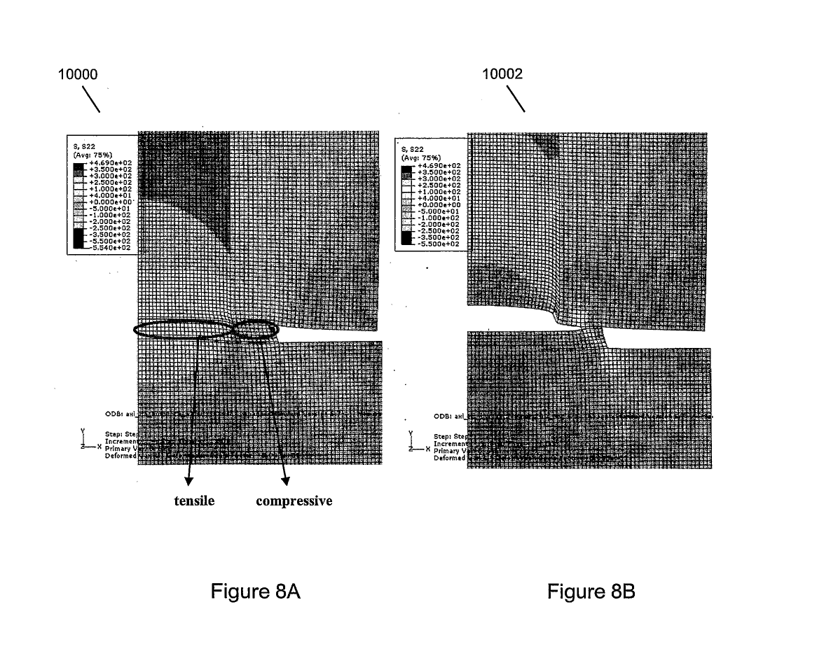

FIG. 7B shows one partially filled bond pad portion 104 positioned on one surface of an interconnect portion 116 and a fully filled bond pad portion 128 positioned on an opposite surface of the interconnect portion 116. In more details, FIG. 8B shows a partially filled bond pad portion 104 positioned between the interconnect portion 116 and the conductive portion 114 and a fully filled further bond pad portion 128 positioned between the interconnect portion 116 and the further semiconductor arrangement 124. The partially filled bond pad portion 104 may include a bond pad circumferential portion 106 arranged at least partially circumferential with respect to the via 112 at a first distance (d) away from the conductive portion 114; and at least one bond pad electrical connection 118 extending from within the bond pad circumferential portion 106 to the conductive portion 114; wherein the interconnect portion 116 may be arranged away from the conductive portion 114 via the bond pad portion 104.

A model of the stacked arrangement as shown in FIG. 7B may be made to undergo a temperature ramp down from about 180° C. to about 25° C. It may be assumed that at about 180° C., the model of the stacked arrangement may be at a stress-free state.

FIG. 8A shows a stress contour plot 10000 of stress contours in an axial direction of the simulation model of the stack arrangement 102 as shown in FIG. 7A according to an embodiment; FIG. 8B shows a stress contour plot 10002 of stress contours in an axial direction of the simulation model of the stack arrangement 102 as shown in FIG. 7B according to an embodiment.

The tensile stress contours in the models of the stack arrangement 102 as shown in FIG. 7A and FIG. 7B may be shown in respective FIG. 8A and FIG. 8B.

The deformed configuration of the respective models of the stack arrangement 102 as shown in FIG. 8A and FIG. 8B may have been exaggerated by about 50 times. From FIG. 8A and FIG. 8B, it may be clear that the stress in the interconnect portion 116 or joint may be much larger in the fully filled bond pad portion 138 when compared to the partially filled bond pad portion 104. The partially filled bond pad portion 104 or the bond pad portion 104 with the ring pad may generally not be under stress except at the corners of the bond pad portion 104

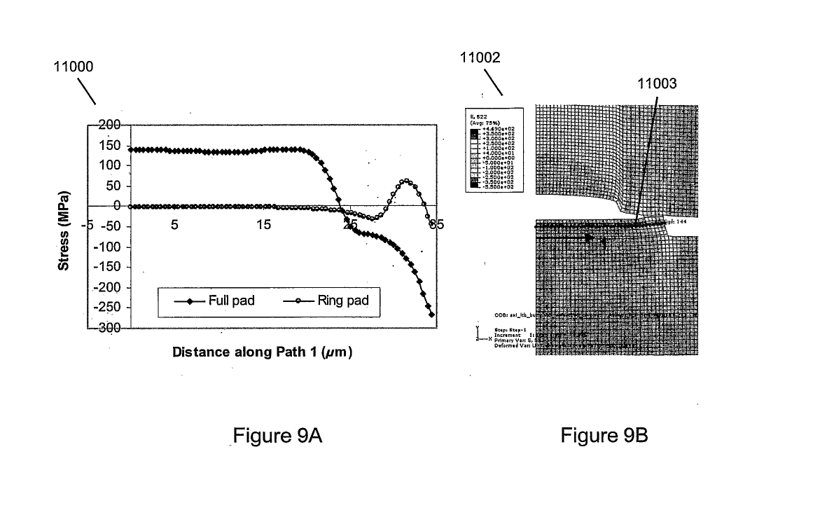

FIG. 9A shows a plot 11000 of stress versus distance along a mid-plane of an interconnect portion 116 for a respective fully filled bond pad portion 138 and a partially filled bond pad portion 104 according to an embodiment; FIG. 9B shows a stress contour plot 11002 of stress contours in an axial direction of a simulation model of a stack arrangement 102 including a partially filled bond pad portion 104 according to an embodiment.

FIG. 9A shows that with the bond pad portion 138 including a fully filled bond pad design, the interconnect portion 116 or joint may be in a general state of high stress (about 150 MPa) at the center as the conductive portion 114 (or copper) may deform most in the z-direction. On the other hand, with the partially filled bond pad portion 104 including a ring bond pad design, the stress at the center may decrease to zero because the contraction of the conductive portion 114 (or copper) in the via 112 no longer pulls the partially filled bond pad 104 and then bond upwards. There may be a comparatively higher stress at the edges of the partially filled bond pad portion 104 with the ring bond pad design.

From FIG. 9A, it may be seen that the maximum tensile stress in the interconnect portion 116 or joint may decrease by about 50% with use of the partially filled bond pad portion 104 or the ring bond pad. In addition, the bond length which may experience maximum stress may decrease from about 50% in the normal bond pad to about 4% in the ring bond pad 104. This general decrease in the stress state of the interconnect portion 116 or joint may increase its reliability.

FIG. 9B shows the stress contour plot 11002 of the stack arrangement 102 including the partially filled bond pad portion 104, the interconnect portion 116, the via 112 and the silicon substrate 110. The stress in the stress contour plot 11002 may be extracted through the interconnect portion 116 (along the line 11003 as shown in FIG. 9B).

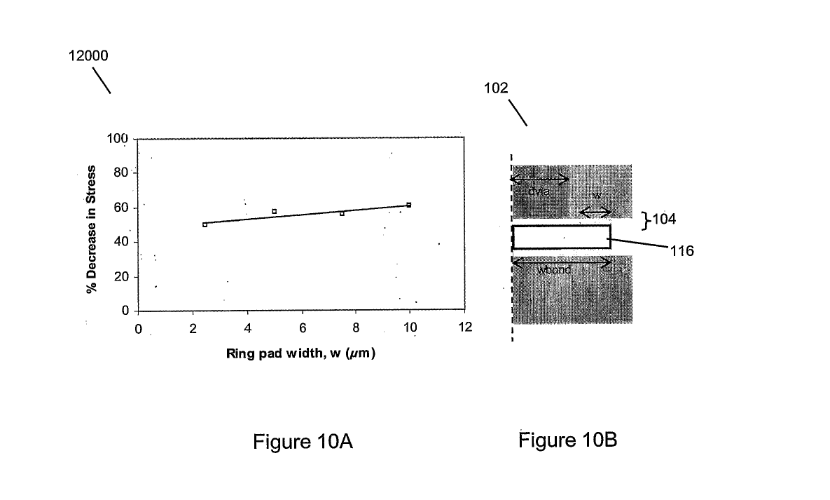

FIG. 10A shows a plot 12000 of percentage decrease in stress versus bond pad circumferential portion width according to an embodiment; FIG. 10B shows a side view of a stack arrangement 102 including a partially filled bond pad portion 104 according to an embodiment.

A simulation may be carried out to determine an optimum width, w, of the ring bond pad portion 104 for a given TSV diameter (dvia) of about 25 μm and a bond pad diameter (wbond) of about 35 μm. The outer diameter of the ring bond pad portion 104 may be fixed so that varying the width may only change the inner diameter of the bond pad portion 104.

FIG. 10A shows the results obtained. The results may show that for different widths of the ring bond pad, the percentage decrease in stress in the interconnect portion 116 or joint may range from about 50% to about 60%.

The stack arrangement 102 as shown in FIG. 10B may be similar to the stack arrangement 102 as shown in FIG. 8B.

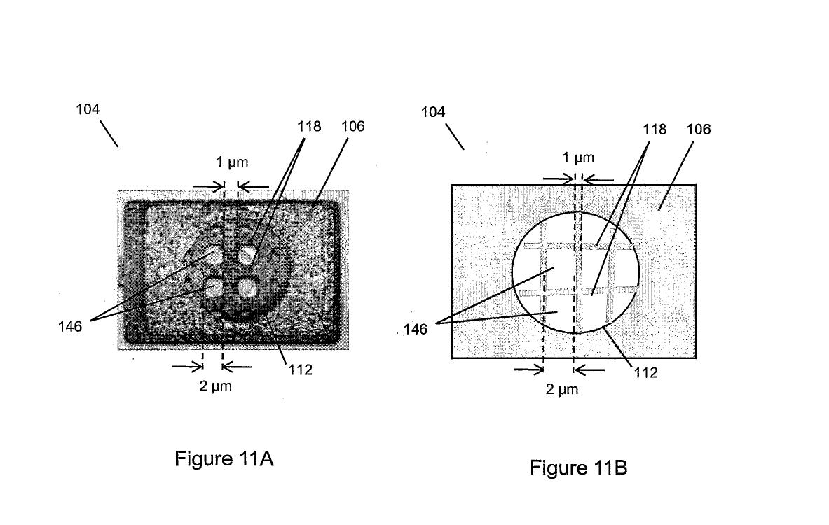

FIG. 11A shows a top view image of a bond pad portion 104 according to an embodiment and FIG. 11B shows a corresponding schematic view of the bond pad portion 104 of FIG. 11A according to an embodiment. The bond pad portion 104 may include a bond pad circumferential portion 106 arranged at least partially circumferential with respect to the via 112 and at a first distance away from the conductive portion (not shown). The bond pad portion 104 may further include a plurality of bond pad electrical connections 118 extending from within the bond pad circumferential portion 106 to the conductive portion. The plurality of bond pad electrical connections 118 may be arranged within the bond pad circumferential portion 106 such that a plurality of openings 146 may be formed within the bond pad circumferential portion 106. Each of the plurality of openings 146 may be of a same or different cross-sectional area. For example, the average width of each of the plurality of openings 146 may be about 2 μm and the distance between each of the plurality of openings 146 or the width of each of the plurality of bond pad electrical connections 118 may be about 1 μm as indicated in FIGS. 11A and 11B. Other dimension and trace patterns may be adopted depending on user and design requirements.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A stack arrangement comprising:
a semiconductor arrangement, the semiconductor arrangement comprising:
a substrate;
a via formed through the substrate; and
a conductive portion arranged in the via;
an interconnect portion arranged over the via;
a bond pad portion arranged between the semiconductor arrangement and the interconnect portion, the bond pad portion comprising:
a bond pad circumferential portion arranged at least partially circumferential with respect to the via and at a first distance away from the conductive portion; and
at least one bond pad electrical connection extending from within the bond pad circumferential portion to the conductive portion;
wherein the interconnect portion is arranged away from the conductive portion via the bond pad portion.

2. The stack arrangement of claim 1,
wherein the conductive portion fills the via.

3. The stack arrangement of claim 1,
wherein the via comprises at least one sidewall.

4. The stack arrangement of claim 3,
wherein the conductive portion is arranged along the at least one sidewall of the via.

5. The stack arrangement of claim 1,
wherein the interconnect portion comprises a filled portion or an interconnect circumferential portion surrounding a hollow body.

6-8. (canceled)

9. The stack arrangement of claim 1,
wherein the bond pad circumferential portion at least partially surrounds an opening of the via.

10. The stack arrangement of claim 1,
wherein the bond pad circumferential portion comprises a thickness greater than a thickness of the at least one bond pad electrical connection.

11-13. (canceled)

14. The stack arrangement of claim 5,
wherein the bond pad circumferential portion is aligned with the interconnect circumferential portion.

15. The stack arrangement of claim 1,
wherein the at least one bond pad electrical connection extends from the bond pad circumferential portion along a surface of the substrate to the conductive portion.

16. The stack arrangement of claim 1,
wherein the at least one bond pad electrical connection comprises a plurality of bond pad electrical connections.

17. The stack arrangement of claim 16,
wherein the plurality of bond pad electrical connections are arranged within the bond pad circumferential portion such that the plurality of bond pad electrical connections are linked at a common position.

18. The stack arrangement of claim 1,
further comprising a further semiconductor arrangement arranged over the interconnect portion.

19. The stack arrangement of claim 18,
wherein the further semiconductor arrangement comprises a further substrate.

20. The stack arrangement of claim 19,
wherein the further semiconductor arrangement further comprises:
a further via formed in the further substrate; and
a further conductive portion arranged in the further via.

21. The stack arrangement of claim 20,
wherein the further conductive portion fills the further via.

22. The stack arrangement of claim 20,
wherein the further via comprises at least one sidewall.

23. The stack arrangement of claim 22,
wherein the further conductive portion is arranged along the at least one sidewall of the further via.

24. The stack arrangement of claim 18,
further comprising a further bond pad portion arranged between the further semiconductor arrangement and the interconnect portion.

25. The stack arrangement of claim 24,
wherein the further bond pad portion comprises a filled portion.

26. The stack arrangement of claim 24,
wherein the further bond pad portion comprises:
a further bond pad circumferential portion arranged at least partially circumferential with respect to the further via and at a second distance away from the further conductive portion; and
at least one further bond pad electrical connection extending from the further bond pad circumferential portion to the further conductive portion.

27-35. (canceled)
